(19) United States
(12) Patent Application Publication
(10) Pub. No.: US 2026/0100432 A1
(43) Pub. Date: Apr. 9, 2026

(54) METHOD AND APPARATUS FOR EVALUATING LIFETIME OF SECONDARY BATTERY

(71) Applicant: SAMSUNG SDI CO., LTD., Yongin-si (KR)

(72) Inventor: Minhee JOO, Yongin-si (KR)

(21) Appl. No.: 19/295,852

(22) Filed: Aug. 11, 2025

(30) Foreign Application Priority Data
Oct. 4, 2024 (KR) 10-2024-0134854

(51) Int. Cl. H01M 10/48; G01R 31/367; G01R 31/392; H01M 10/42; H01M 10/44

(52) U.S. Cl. CPC H01M 10/488; G01R 31/367; G01R 31/392; H01M 10/425; H01M 10/44; H01M 2010/4278

(57) ABSTRACT

A method of evaluating a lifetime of a secondary battery, the method including receiving, via a data receiver, monitoring data of the secondary battery over charge and discharge cycles; determining, via a parameter determiner, a degradation prediction parameter of the secondary battery based on the monitoring data; and evaluating, via a lifetime evaluator, lifetime characteristics of the secondary battery based on the degradation prediction parameter.

### CROSS-REFERENCE TO RELATED APPLICATION

The present application claims priority to and the benefit of Korean Application No. 10-2024-0134854, filed on Oct. 4, 2024, in the Korean Intellectual Property Office, the entire disclosure of which is incorporated by reference herein.

### BACKGROUND

### Field

The present disclosure relates to a method and apparatus for evaluating the lifetime of a secondary battery and an apparatus for the same.

### Description of the Related Art

Unlike primary batteries that are not designed to be (re) charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

When developing a secondary battery, to guarantee the lifetime of the secondary battery, charging and discharging may be performed repeatedly under similar conditions, and for a similar duration, to the actual usage environment of the secondary battery. In this way, by measuring a lifetime (or, a remaining charging capacity) of the secondary battery, a long-term lifetime of the secondary battery may be predicted and a degradation status of the secondary battery may be identified at the same time, so that lifetime characteristics of the secondary battery may be evaluated. However, this method of evaluating a lifetime of a secondary battery is time-consuming and cumbersome. In addition, it is not easy to distinguish a degradation of the positive electrode and a degradation the negative electrode within the secondary battery, so it may be difficult to accurately identify a cause of the degradation of the secondary battery.

The above information disclosed in this Background section is for enhancement of understanding of the background of the present disclosure, and therefore, it may contain information that does not constitute related (or prior) art.

### SUMMARY

An object that the present disclosure seeks to achieve is to provide a method and apparatus for evaluating the lifetime of a secondary battery to solve the above problem.

These and other aspects and features of the present disclosure will be described in or will be apparent from the following description of embodiments of the present disclosure.

Some embodiments of the present disclosure for achieving the above technical objective include a method of evaluating a lifetime of a secondary battery, the method including receiving, via a data receiver, monitoring data of the secondary battery over charge and discharge cycles; determining, via a parameter determiner, a degradation prediction parameter of the secondary battery based on the monitoring data; and evaluating, via a lifetime evaluator, lifetime characteristics of the secondary battery based on the degradation prediction parameter.

According to some embodiments of the present disclosure, the method further includes receiving monitoring data including at least one of voltage data, current data, or battery capacity data of the secondary battery over multiple charge and discharge cycles.

According to some embodiments of the present disclosure, each of the multiple charge and discharge cycles includes, in sequence, a constant current charging section in which the secondary battery is charged at a constant current, a constant voltage charging section in which the secondary battery is charged at a constant voltage, a rest after charging section in which charging of the secondary battery is stopped, a constant current discharging section in which the secondary battery is discharged at a constant current, and a rest after discharging section in which discharging of the secondary battery is stopped, the method further including computing voltage data of the secondary battery measured at an end time of the rest after discharging section of a specific charge and discharge cycle to determine the degradation prediction parameter of the secondary battery.

According to some embodiments of the present disclosure, computing voltage data of the secondary battery measured at an end time of the rest after discharging section of the specific charge and discharge cycle further includes computing voltage data of the secondary battery measured at an end time of the rest after discharging section of a first charge and discharge cycle, the first charge and discharge cycle being the specific charge and discharge cycle.

According to some embodiments of the present disclosure, evaluating lifetime characteristics of the secondary battery further includes determining whether a positive electrode of the secondary battery is deteriorated, the positive electrode of the secondary battery being deteriorated when the degradation prediction parameter is greater than or equal to a preset threshold voltage.

According to some embodiments of the present disclosure, the method further includes conducting a reference performance test of the secondary battery once for every preset number of charge and discharge cycles among the multiple charge and discharge cycles.

According to some embodiments of the present disclosure, receiving monitoring data further includes receiving (i) initial battery capacity data of the secondary battery, (ii) first battery capacity data obtained at a charge and discharge cycle immediately before a specific reference performance test, and (iii) second battery capacity data obtained at a charge and discharge cycle immediately after the specific reference performance test, and determining a degradation prediction parameter further includes determining the degradation prediction parameter based on (i) the initial battery capacity data, (ii) the first battery capacity data, and (iii) the second battery capacity data.

According to some embodiments of the present disclosure, determining the degradation prediction parameter further includes determining a ratio of a difference between the first battery capacity data and the second battery capacity data.

According to some embodiments of the present disclosure, evaluating lifetime characteristics of the secondary battery further includes determining whether a positive electrode of the secondary battery is deteriorated, the positive electrode of the secondary battery being deteriorated when the determined degradation prediction parameter is greater than or equal to a preset threshold ratio.

According to some embodiments of the present disclosure, the method further includes setting the preset threshold ratio to less than or equal to 1 percent.

According to some embodiments of the present disclosure, the method further includes performing the multiple charge and discharge cycles having a preset first charge and discharge rate and conducting the reference performance test under a second charge and discharge rate that is lower than the preset first charge and discharge rate.

According to some embodiments of the present disclosure, conducting the reference performance test under a second charge and discharge rate further includes conducting the reference performance test under a second charge and discharge rate that is 10 to 50 percent of the preset first charge and discharge rate.

According to some embodiments of the present disclosure, the method further includes performing the multiple charge and discharge cycles at a preset number of charge and discharge cycles that is greater than or equal to 1 and less than or equal to 200.

Some embodiments of the present disclosure for achieving the above technical objective include a device for evaluating a lifetime of a secondary battery, the device including a data receiver configured to receive monitoring data of the secondary battery over charge and discharge cycles, a parameter determiner configured to determine a degradation prediction parameter of the secondary battery based on the monitoring data, and a lifetime evaluator configured to evaluate lifetime characteristics of the secondary battery based on the degradation prediction parameter.

According to some embodiments of the present disclosure, the monitoring data includes at least one of voltage data, current data, or battery capacity data of the secondary battery over multiple charge and discharge cycles.

According to some embodiments of the present disclosure, each of the multiple charge/discharge cycles may include, in sequence, a constant current charging section in which the secondary battery is charged at a constant current, a constant voltage charging section in which the secondary battery is charged at a constant voltage, a rest after charging section in which charging of the secondary battery is stopped, a constant current discharging section in which the secondary battery is discharged at a constant current, and a rest after discharging section in which discharging of the secondary battery is stopped, the parameter determiner is configured to determine the degradation prediction parameter of the secondary battery by computing voltage data of the secondary battery, the voltage data measured at an end time of the rest after discharging section of a specific charge and discharge cycle, and the lifetime evaluator is configured to determine that a positive electrode of the secondary battery is deteriorated when the degradation prediction parameter is greater than or equal to a preset threshold voltage.

According to some embodiments of the present disclosure, the specific charge and discharge cycle is a first charge and discharge cycle among the multiple charge and discharge cycles.

According to some embodiments of the present disclosure, a reference performance test of the secondary battery is conducted once for every preset number of charge and discharge cycles among the multiple charge and discharge cycles, the data receiver is configured to receive (i) initial battery capacity data of the secondary battery, (ii) first battery capacity data obtained at a charge and discharge cycle immediately before a specific reference performance test, and (iii) second battery capacity data obtained at a charge and discharge cycle immediately after the specific reference performance test, the parameter determiner is configured to determine the degradation prediction parameter based on (i) the initial battery capacity data, (ii) the first battery capacity data, and (iii) the second battery capacity data, and the lifetime evaluator is configured to determine whether a positive electrode of the secondary battery is deteriorated, the positive electrode being deteriorated when the determined degradation prediction parameter is greater than or equal to a preset threshold ratio.

According to some embodiments of the present disclosure, the degradation prediction parameter is determined to be a ratio of a difference between the first battery capacity data and the second battery capacity data with respect to the initial battery capacity data.

According to some embodiments of the present disclosure, the preset threshold ratio is less than or equal to 1 percent.

According to some embodiments of the present disclosure, based on the voltage change pattern of the secondary battery, the voltage change pattern of the positive electrode of the secondary battery may be estimated. In addition, by using a method for estimating the voltage change pattern of the positive electrode of a secondary battery, it is possible to predict, in a non-destructive manner, whether the positive electrode of the secondary battery is deteriorated, without disassembling the secondary battery.

According to some embodiments of the present disclosure, the lifetime evaluation apparatus for a secondary battery may predict whether the secondary battery has deteriorated and/or long-term lifetime characteristics based on the initial lifetime data of the secondary battery. Hence, an efficiency of the lifetime evaluation method for the secondary battery may be increased, and a manufacturing efficiency of the secondary battery may be improved by evaluating a quality of the secondary battery at an early stage.

According to some embodiments of the present disclosure, the lifetime characteristics of a secondary battery may be evaluated according to both a first degradation prediction parameter and a second degradation prediction parameter calculated based on monitoring data of the secondary battery. Thereby, an accuracy of lifetime evaluation results may be increased by cross validating the lifetime evaluation results.

However, aspects and features of the present disclosure are not limited to those described above, and other aspects and features not mentioned will be clearly understood by a person skilled in the art from the detailed description, described below.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is a block diagram of a lifetime evaluation system according to some embodiments of the present disclosure.

FIG. 2 is a block diagram of a process of manufacturing a secondary battery evaluated by a lifetime evaluation system according to some embodiments of the present disclosure.

FIG. 3 is a block diagram of an information processing system used in the lifetime evaluation system for a secondary battery according to some embodiments of the present disclosure.

FIG. 4 is a graph for an exemplary method of determining whether the positive electrode of a secondary battery is deteriorated based on voltage data of the secondary battery according to some embodiments of the present disclosure.

FIG. 5 is another graph for an exemplary method of determining whether the positive electrode of a secondary battery is deteriorated based on voltage data of the secondary battery according to some embodiments of the present disclosure.

FIG. 6 is another graph for an exemplary method of determining whether the positive electrode of a secondary battery is deteriorated based on voltage data of the secondary battery according to some embodiments of the present disclosure.

FIG. 7 is a graph for an exemplary a method of determining whether the positive electrode of a secondary battery is deteriorated based on battery capacity data of the secondary battery according to some embodiments of the present disclosure.

FIG. 8 is a chart for an exemplary a method of determining whether the positive electrode of a secondary battery is deteriorated based on battery capacity data of the secondary battery according to some embodiments of the present disclosure.

FIG. 9 is a graph showing a correlation between a first degradation prediction parameter and a second degradation prediction parameter.

FIG. 10 is another graph showing a correlation between a first degradation prediction parameter and a second degradation prediction parameter.

FIG. 11 is a flowchart for a method of evaluating the lifetime of a secondary battery according to some embodiments of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meanings and concepts that are consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

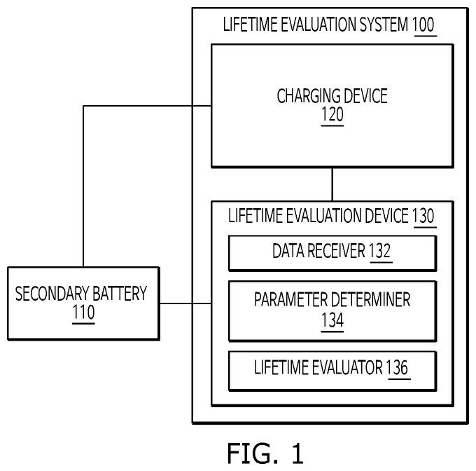

FIG. 1 is a block diagram of a lifetime evaluation system according to some embodiments of the present disclosure. The lifetime evaluation system 100 may include a charging device 120 and a lifetime evaluation device 130. The lifetime evaluation device 130 may include a data receiver 132, a parameter determiner 134, and a lifetime evaluator 136. The lifetime evaluation system 100 may be connected to a secondary battery 110 (or manufacturing process equipment for manufacturing a secondary battery) to evaluate the lifetime of the secondary battery 110.

The charging device 120 of the lifetime evaluation system 100 may be connected to the secondary battery 110 and may repeatedly charge and discharge the secondary battery 110. The charging device 120 may control a magnitude of the current applied to the secondary battery 110 or a time for which the current is applied, according to preset lifetime evaluation test conditions for the secondary battery.

The lifetime evaluation device 130 of the lifetime evaluation system 100 may evaluate the lifetime characteristics of the secondary battery 110 based on monitoring data collected during a process of charging and discharging the secondary battery 110.

The data receiver 132 of the lifetime evaluation device 130 may receive monitoring data of the secondary battery 110 over multiple charge and discharge cycles. The monitoring data may include at least one of voltage data, current data, or battery capacity data of the secondary battery 110 over multiple charge and discharge cycles. The voltage data of the secondary battery 110 may include, but is not limited to, voltage profile data for a battery capacity (e.g., a charging capacity or a discharging capacity) of the secondary battery 110. Additionally, the battery capacity data of the secondary battery may include, but not limited to, data on the battery capacity of the secondary battery 110 over multiple charge and discharge cycles.

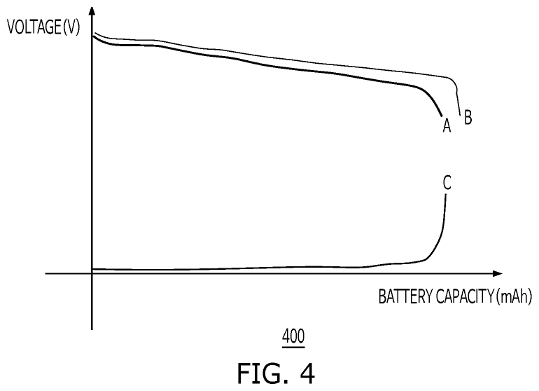

The parameter determiner 134 of the lifetime evaluation device 130 may determine a degradation prediction parameter of the secondary battery 110 based on monitoring data received from the data receiver 132. The degradation prediction parameter may be a parameter for predicting whether the positive electrode of the secondary battery 110 is deteriorated. Examples of determining degradation prediction parameters of the secondary battery 110 are described in further detail with reference to FIGS. 4 to 10.

The lifetime evaluator 136 of the lifetime evaluation device 130 may evaluate the lifetime characteristics of the secondary battery 110 based on the determined degradation prediction parameter. For example, the lifetime evaluator 136 can determine that the positive electrode of the secondary battery 110 is deteriorated if a first degradation prediction parameter, determined based on the voltage data of the secondary battery 110, is greater than a threshold voltage value. In contrast, the lifetime evaluator 136 may determine that the positive electrode of the secondary battery 110 is not deteriorated if the first degradation prediction parameter is less than the threshold voltage value.

Similarly, the lifetime evaluator 136 may determine that the positive electrode of the secondary battery 110 is deteriorated if a second degradation prediction parameter, determined based on the battery capacity data of the secondary battery 110, is greater than a threshold ratio. In addition, the lifetime evaluator 136 may determine that the positive electrode of the secondary battery 110 is not deteriorated if the second degradation prediction parameter is less than the threshold ratio. Examples of determining whether the secondary battery 110 is deteriorated based on the first degradation prediction parameter or the second degradation prediction data of the secondary battery 110 will be described in further detail with reference to FIGS. 4 to 10.

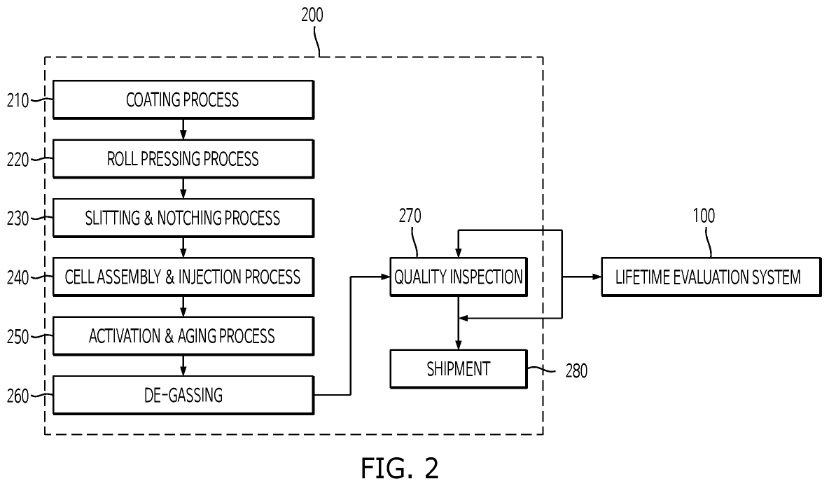

FIG. 2 is a block diagram of a process of manufacturing a secondary battery evaluated by a lifetime evaluation system according to some embodiments of the present disclosure. The lifetime evaluation system 100 may predict the lifetime of a secondary battery by using the lifetime evaluation device interworking with a manufacturing process equipment 200. In addition, the lifetime evaluation system 100 may evaluate the quality of the secondary battery based on the predicted lifetime. For example, the lifetime characteristics of a secondary battery manufactured by the manufacturing process 200 may be evaluated by the lifetime evaluation device of the lifetime evaluation system 100, and the lifetime of the secondary battery may be predicted based on an evaluation of the secondary battery by the lifetime evaluation device.

Meanwhile, the manufacturing process equipment 200 may manufacture a secondary battery based on design specifications of the secondary battery. In addition, the manufacturing process equipment 200 may test a quality of the manufactured secondary battery based on a lifetime prediction result and/or a lifetime evaluation result produced by the lifetime evaluation system 100.

The manufacturing process equipment 200 may perform the manufacturing process and quality inspection process of the secondary battery. For example, the manufacturing process of the secondary battery may include a coating process 210, a roll pressing process 220, a slitting and notching process 230, a cell assembly and injection process 240, an activation and aging process 250, and a degassing process 260. In addition, the quality inspection process of the secondary battery may include quality inspection 270 and shipment 280.

Particularly, the coating process 210 may be a process of coating a slurry containing a positive electrode active material or a negative electrode active material on a substrate of a secondary battery or a current collector of a secondary battery. The roll pressing process 220 may be a process of flatly rolling the electrode of the secondary battery coated with an active material, or the like. The slitting and notching process 230 may be a process of cutting the electrode to fit the size of the secondary battery, and forming and processing the electrode tabs, or the like. The cell assembly and injection process 240 may include a process of injecting an electrolyte into a case of the secondary battery after assembling the secondary battery. The activation and aging process 250 may be a process of stabilizing the secondary battery through charging and discharging the secondary battery. The degassing process 260 may be a process of removing gas generated in the activation and aging process 250 from inside the secondary battery.

In some embodiments, when a new target secondary battery is developed according to customer's requirements, the lifetime evaluation system 100 may receive evaluation condition data for evaluating the target secondary battery. Meanwhile, the target secondary battery may be manufactured by the manufacturing process equipment 200 according to its specification. When carrying out quality inspection 270 of the target secondary battery, the manufacturing process equipment 200 may transfer the evaluation condition data of the target secondary battery to the lifetime evaluation system 100. The lifetime evaluation system 100 may predict the lifetime of the target secondary battery based on the specification of the target secondary battery and/or the evaluation condition data of the target secondary battery and may evaluate the quality of the target secondary battery. Thereafter, the lifetime evaluation system 100 may transfer the predicted lifetime and quality evaluation results of the target secondary battery to the manufacturing process 200. Thereby, the manufacturing process equipment 200 may determine whether a predicted lifetime of the target secondary battery satisfies a customer's requirements in the quality inspection process 270. If the target secondary battery fails to satisfy the customer's requirements, the manufacturing process 200 may not perform the shipment process 280 until the secondary battery satisfies the customer's requirements. If the secondary battery satisfies the customer's requirements, the manufacturing process 200 may perform the shipment process 280 to ship the target secondary battery.

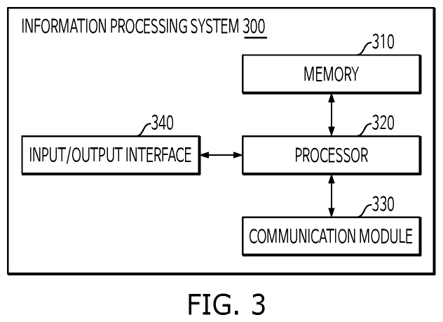

FIG. 3 is a block diagram of an information processing system used in the lifetime evaluation system for a secondary battery according to some embodiments of the present disclosure. The information processing system 300 illustrated in FIG. 3 may correspond to at least one of, for example, the charging device 120 and the lifetime evaluation device 130 shown in FIG. 1. The information processing system 300 may include a memory 310, a processor 320, a communication module 330, and an input/output interface 340. The information processing system 300 may be configured to communicate information and/or data through a network by using the communication module 330. In an embodiment, the information processing system 300 may include at least one of the memory 310, the processor 320, the communication module 330, and the input/output interface 340.

The memory 310 may include any non-transitory computer-readable recording medium. In some embodiments, the memory 310 may include a permanent mass storage device such as a read only memory (ROM), a disk drive, a solid-state drive (SSD), or a flash memory. As another example, a permanent mass storage device such as a ROM, an SSD, a flash memory, or a disk drive may be included in the information processing system 300 as a separate permanent storage device that is distinct from the memory 310. In addition, the memory 310 may store software components including an operating system and at least one program code (e.g., code, for determining a degradation prediction parameter and/or for evaluating the lifetime of a secondary battery, installed in and operated by the information processing system 300).

The software components may be loaded from a computer-readable recording medium, separate from the memory 310. The computer-readable recording medium, separate from the memory 310, may be directly connectable to the information processing system 300 and/or may include, for example, a floppy drive, a disk, a tape, a DVD/CD-ROM drive, or a memory card. As another example, software components other than a computer-readable recording medium may be loaded onto the memory 310 through the communication module 330. For example, at least one program may be loaded onto the memory 310 based on a computer program (e.g., a program for determining degradation prediction parameters and/or for evaluating the lifetime of a secondary battery) installed by files provided over the communication module 330 by developers or by a file distribution system, which distributes installation files for applications.

The processor 320 may be configured to process instructions of a computer program by performing basic arithmetic, logic, and input/output operations. The instructions may be provided by the memory 310 to a user terminal (not shown), or to another external system, via the communication module 330. For example, the processor 320 may receive monitoring data of a target secondary battery from one or more secondary batteries (or, from the manufacturing process equipment for the secondary battery), determine a degradation prediction parameter based on the monitoring data, and evaluate the lifetime characteristics of the secondary battery based on the degradation prediction parameter.

The communication module 330 may provide a configuration or function for the user terminal (not shown) and the information processing system 300 so that the user terminal and the information processing system 300 may communicate with each other through the network. The communication module 330 may also provide a configuration or function for the information processing system 300 to communicate with an external system (e.g., a manufacturing facility for the target secondary battery, a separate cloud system, etc.). In an embodiment, a control signal, a command, or data provided under the control of the processor 320 of the information processing system 300 may be transmitted through the communication module 330 over the network and may be received by the user terminal (and/or the external system) via communication modules of the user terminal (and/or of the external system). For example, the predicted degradation determination information or lifetime evaluation information of the target secondary battery generated by the information processing system 300 may be transmitted through the communication module 330 over the network to the user terminal (and/or to the external system) via the communication modules of the user terminal (and/or the external system). Additionally, the user terminal (and/or external system), after having received the predicted degradation determination information or the lifetime evaluation information, may output the received information through display-output-capable devices.

In addition, the input/output interface 340 of the information processing system 300 may allow for interfacing with a device (not shown) for input or output, the device able to be connected to or included in the information processing system 300. In FIG. 3, the input/output interface 340 is a separate component from the processor 320, in other embodiments, the input/output interface 340 may be included in the processor 320. The information processing system 300 may include more components than those shown in FIG. 3.

The processor 320 of the information processing system 300 may be configured to manage, process, and/or store information and/or data received from a plurality of user terminals and/or a plurality of external systems. According to an embodiment, the processor 320 may receive monitoring data of a target secondary battery or the like from a user terminal and/or an external system. The processor 320 may determine a degradation prediction parameter based on the monitoring data of the target secondary battery, evaluate the lifetime characteristics of the secondary battery based on the degradation prediction parameter, and output degradation determination information, lifetime evaluation information, and/or the like through a display-output-capable device connected to the information processing system 300.

FIG. 4 is a graph for an exemplary method of determining whether the positive electrode of a secondary battery is deteriorated based on voltage data of the secondary battery according to some embodiments of the present disclosure. The graph 400 may represent a change in voltage with respect to a battery capacity during a process of discharging the secondary battery. The first curve A shows a change in voltage of the secondary battery according to a change in battery capacity, the second curve B shows the change in voltage of the positive electrode according to the change in battery capacity, and the third curve C shows the change in voltage of the negative electrode according to the change in battery capacity. The voltage of the secondary battery may be the voltage of the positive electrode minus the voltage of the negative electrode.

In FIG. 4, the voltage of the secondary battery may continuously decrease as the secondary battery capacity changes. An initial voltage of the positive electrode may be higher than an initial voltage of the negative electrode. In addition, as the secondary battery capacity changes as the secondary battery is discharged, the voltage of the positive electrode may continuously decrease, and the voltage of the negative electrode may continuously increase. Hence, the voltage of the secondary battery, which is the voltage of the positive electrode of the secondary battery minus the voltage of the negative electrode of the secondary battery, may also continuously decrease.

In an embodiment, during a process of discharging of the secondary battery, the voltage of the secondary battery may vary depending on voltage characteristics of the positive electrode. In FIG. 4, the first curve A (representing the voltage change of the secondary battery) and the second curve B (representing the voltage change of the positive electrode of the secondary battery) show substantially similar patterns. That is, during the process of discharging of the secondary battery, the voltage change of the positive electrode may be a factor affecting the voltage change of the secondary battery.

In an embodiment, the secondary battery may experience a voltage drop phenomenon in which the voltage decreases rapidly at the final stage of the process of discharging the secondary battery. For example, the voltage of the positive electrode of the secondary battery may decrease rapidly, and the voltage of the negative electrode of the secondary battery may increase rapidly. As a result, the voltage of the secondary battery may also decrease rapidly.

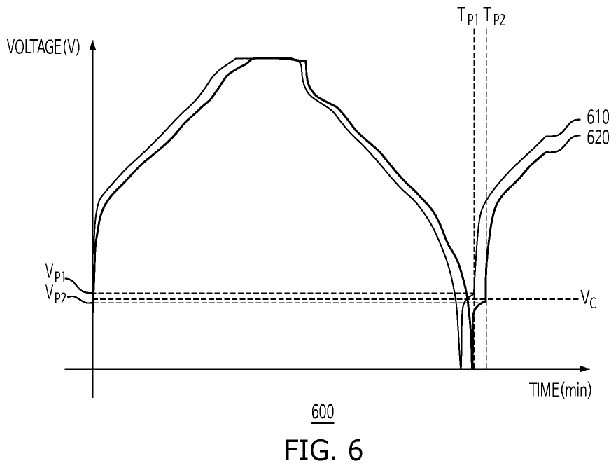

The voltage drop phenomenon at the final discharge stage of the secondary battery may be associated with a degradation phenomenon of the positive electrode. For example, when the positive electrode deteriorates, a positive electrode resistance may increase due to physical and chemical changes in a material of the positive electrode, which may result in a large voltage drop for the positive electrode. Hence, when the positive electrode deteriorates, the voltage drop of the secondary battery may also increase. An example of how the voltage of a secondary battery changes depending on a resistance of the positive electrode will be described later with reference to FIG. 6.

According to voltage change data, described above in reference to FIG. 4, of the secondary battery the voltage change pattern of the positive electrode of the secondary battery may be estimated based on a voltage change pattern at a final stage of discharging the secondary battery. In addition, by using the method of estimating the voltage change pattern of the positive electrode of the secondary battery, it is possible to predict whether the positive electrode of the secondary battery is deteriorated in a non-destructive manner, without disassembling the secondary battery.

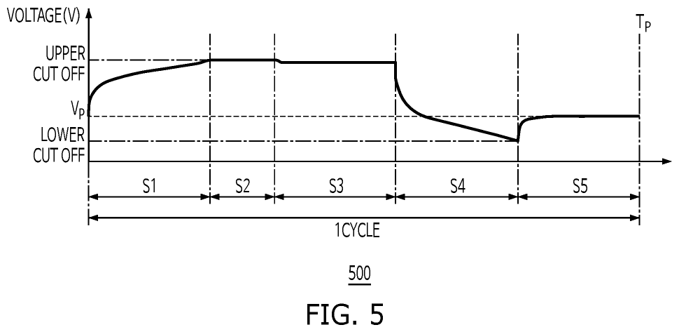

FIG. 5 is another graph for an exemplary method of determining whether the positive electrode of a secondary battery is deteriorated based on voltage data of the secondary battery according to some embodiments of the present disclosure. The graph 500 may represent an example of voltage data of a secondary battery received by a lifetime evaluation device (e.g., the lifetime evaluation device 130 in FIG. 1). The lifetime evaluation device may receive voltage data of the secondary battery over multiple charge and discharge cycles. Additionally, the lifetime evaluation device may determine a first degradation prediction parameter V_{P} of the secondary battery based on received voltage data of the secondary battery.

The graph 500 may represent an example of voltage data of a secondary battery measured for one charge and discharge cycle. The charge and discharge cycle of the secondary battery may include a constant current (CC) charging section S1, a constant voltage (CV) charging section S2, a rest after charging section S3, a CC discharging section S4, and a rest after discharging section S5. Particularly, the charge and discharge cycle of the secondary battery may include, in sequence, the CC charging section S1, in which the secondary battery is charged at a constant current; the CV charging section S2, in which the secondary battery is charged at a constant voltage when the voltage of the secondary battery reaches an upper cut-off voltage; the rest after charging section S3, in which charging is stopped for a specific period of time; the CC discharging section S4, in which the secondary battery is discharged at a constant current; and the rest after discharging section S5, in which discharging is stopped for a specific period of time when the voltage of the secondary battery reaches a lower cut-off voltage.

In an embodiment, the charge and discharge cycle of the secondary battery may be repeated under conditions similar to the actual usage environment of the secondary battery. For example, in some embodiments, the secondary battery can be charged from 0.3 C to 1 C in the CC charging section S1, the secondary battery may be charged from 4.1 V to 4.3 V in the CV charging section S2, and the secondary battery may be discharged from 0.1 C to 1.0 C or from 2.0 V to 3.0 V in the CC discharging section S4, but the aforementioned charging ranges are exemplary and should not be construed to limit other embodiments. In some embodiments, the time during which the charging and/or discharging of the secondary battery is stopped in the rest after charging section S3 and/or in the rest after discharging section S5 may be from 5 minutes to 30 minutes, but other embodiments may not be limited to such a range. Additionally, in some embodiments, the lifetime evaluation of the secondary battery may be performed at a temperature of 20 degrees Celsius to 45 degrees Celsius, but other embodiments may not be limited to such a range.

According to an embodiment, a voltage drop phenomenon of the secondary battery may occur in the CC discharging section S4, rendering a voltage that has dropped. Thereafter, the voltage that has dropped may be recovered in the rest after discharging section S5, and the voltage may increase again.

The voltage at the time T_{P} when the rest after discharging section S5 is ended may be determined as the first degradation prediction parameter V_{P} of the secondary battery. For example, in some embodiments, the voltage measured at an end time T_{P} of the rest after discharging section S5 of a specific charge and discharge cycle, among multiple charge and discharge cycles (e.g., 200 to 3000 cycles), may be determined as the first degradation prediction parameter V_{P} of the secondary battery. In such an example, the specific charge and discharge cycle may be the first charge and discharge cycle among multiple charge and discharge cycles, but other embodiments are not limited thereto.

FIG. 6 is another graph for an exemplary method of determining whether the positive electrode of a secondary battery is deteriorated based on voltage data of the secondary battery according to some embodiments of the present disclosure. Referring to the graph 600, it may be seen that a voltage change pattern of the secondary battery varies depending on the resistance design of the positive electrode. Particularly, a first embodiment 610 may show voltage data over charge and discharge cycles of a secondary battery of which a positive electrode resistance is designed to be large, and a second embodiment 620 may show voltage data over charge and discharge cycles of a secondary battery of which a positive electrode resistance is designed to be small in comparison to the first embodiment 610.

The voltage at the end time of the rest after discharging section S5 is greater in a battery designed with a large resistance of the positive electrode. That is, a voltage measured at a first time point T_{P1} at which the rest after discharging section S5 ends in the first embodiment 610 (where the resistance of the positive electrode is large) may be greater than a voltage measured at a second time point T_{P2} at which the rest after discharging section S5 ends in the second embodiment 620 (where the resistance of the positive electrode is relatively small).

The voltage measured at the first time point T_{P1} for a secondary battery of the first embodiment 610 may be determined as a first degradation prediction parameter V_{P1} of the secondary battery of the first embodiment 610. Additionally, the voltage measured at the second time point T_{P2} for a secondary battery of the second embodiment 620 may be determined as a first degradation prediction parameter V_{P2} of the secondary battery of the second embodiment 620. That is, the first degradation prediction parameter V_{P1} of the secondary battery of the first embodiment 610 where the resistance of the positive electrode is designed to be large may be greater than the first degradation prediction parameter V_{P2} of the secondary battery of the second embodiment 620 where the resistance of the positive electrode is designed to be relatively small.

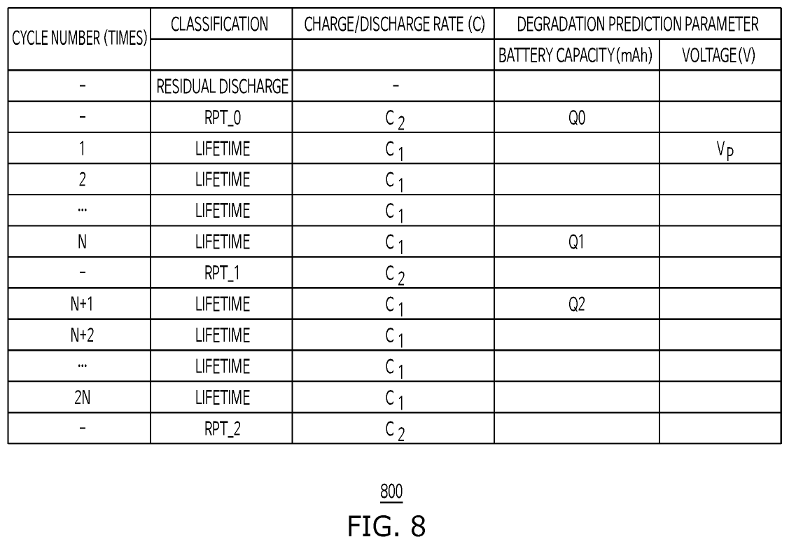

In an embodiment, a component of the lifetime evaluation device (e.g., the lifetime evaluator 136 of the lifetime evaluation device 130 in FIG. 1) may determine whether the negative electrode of the secondary battery is deteriorated based on the first degradation prediction parameter. For example, the lifetime evaluation device may compare the first degradation prediction parameter with a preset threshold voltage V_{C}. If the first degradation prediction parameter is greater than the preset threshold voltage V_{C}, the lifetime evaluation device may determine that the positive electrode of the secondary battery is deteriorated. In addition, if the first degradation prediction parameter is less than the preset threshold voltage V_{C}, the lifetime evaluation device may determine that the positive electrode of the secondary battery is not deteriorated. An example of determining the preset threshold voltage V_{C} for determining the degradation of the positive electrode will be described in detail with reference to FIGS. 8 to 10.

In an embodiment, the first degradation prediction parameter may be determined based on voltage data monitored in at least one charge and discharge cycle among multiple charge and discharge cycles of the secondary battery. The at least one charge and discharge cycle may be determined as a specific charge and discharge cycle among multiple charge and discharge cycles. As a specific example, the at least one charge and discharge cycle may be the first charge and discharge cycle among multiple charge and discharge cycles.

For embodiments as shown in FIG. 8, the lifetime evaluation device for a secondary battery may predict whether the secondary battery has deteriorated and/or predict the long-term lifetime thereof based on initial lifetime data of the secondary battery. Accordingly, efficiency of the lifetime evaluation method of a secondary battery may be increased, and the manufacturing efficiency of a secondary battery may be improved by evaluating the quality of the secondary battery at an early stage.

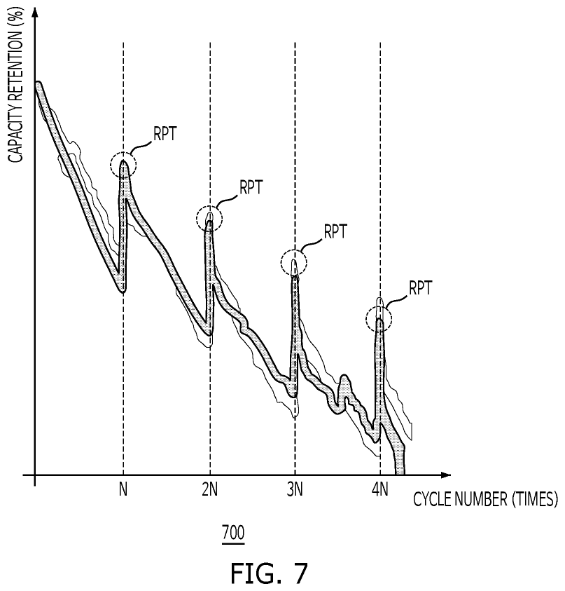

FIG. 7 is a graph for an exemplary a method of determining whether the positive electrode of a secondary battery is deteriorated based on battery capacity data of the secondary battery according to some embodiments of the present disclosure. The graph 700 may represent a trend of a capacity retention ratio (%) over charge and discharge cycles of the secondary battery. The capacity retention ratio may be defined as a ratio of a current capacity of the secondary battery to an initial capacity of the secondary battery.

A reference performance test RPT for a secondary battery may be conducted during a lifetime evaluation process of the secondary battery. The reference performance test RPT can be conducted for every preset number N of charge and discharge cycles among multiple charge and discharge cycles. For example, the reference performance test RPT may be performed once every time a preset number N of charge and discharge cycles are completed. The preset number N of charge and discharge cycles may be greater than or equal to 1 and less than or equal to 200, but other embodiments may not be limited to the aforementioned range.

The reference performance test RPT of the secondary battery may be conducted under a lower charge and discharge rate (current rate or C-rate) condition than the charge and discharge cycle of the secondary battery. Particularly, the reference performance test RPT may be designed to include a CC charging section S1, a CV charging section S2, a rest after charging section S3, a CC discharging section S4, and a rest after discharging section S5 in sequence, similar to the charge and discharge cycle of a secondary battery; but, the charge and discharge rate condition in the CC charging section S1 and/or the CC discharging section S4 may be set differently from that in the charge and discharge cycle.

For example, in some embodiments, the charge and discharge cycle of a secondary battery may proceed under a preset first charge and discharge rate condition, and the reference performance test RPT may be performed under a second charge and discharge rate condition that is lower than the first charge and discharge rate. The second charge and discharge rate may be from 10 percent to 50 percent of the first charge and discharge rate, but other embodiments may not be limited to the aforementioned range.

As a particular example, in some embodiments, for the reference performance test RPT, the secondary battery may be charged at 0.3 C to 0.5 C in the CC charging section S1, the secondary battery may be charged at 4.1 V to 4.3 V in the CV charging section S2, and the secondary battery may be discharged at 0.1 C to 0.5 C and at 2.0 V to 3.0 V in the CC discharging section S4, but other embodiments may not be limited to the aforementioned ranges. In addition, in some embodiments, the time during which charging and/or discharging of the secondary battery is stopped in the rest after charging section S3 and/or the rest after discharging section S5 may be 5 to 30 minutes, but other embodiments are not limited to the aforementioned range.

The lifetime evaluation device may determine a second degradation prediction parameter based on the battery capacity data. The second degradation prediction parameter may be determined based on battery capacity data obtained before and after the reference performance test RPT of the secondary battery.

FIG. 8 is a chart for an exemplary a method of determining whether the positive electrode of a secondary battery is deteriorated based on battery capacity data of the secondary battery according to some embodiments of the present disclosure. The second degradation prediction parameter may be determined based on battery capacity data of a secondary battery over multiple charge and discharge cycles. Table 800 is exemplary of battery capacity data of a secondary battery received by a component of the lifetime evaluation device (e.g., the data receiver 132 of the lifetime evaluation device 130 in FIG. 1). The lifetime evaluation device may determine the second degradation prediction parameter of the secondary battery based on received battery capacity data of the secondary battery. The received battery capacity data may be data including, but not limited to, the charge capacity and/or the discharge capacity of the secondary battery.

Referring to Table 800, a reference performance test RPT of the secondary battery may be conducted every preset number N of charge and discharge cycles among multiple charge and discharge cycles. For example, after starting the lifetime evaluation test of a secondary battery, a first reference performance test RPT_1 may be conducted after N charge and discharge cycles (e.g., a first charge and discharge cycle to an N^{th} charge and discharge cycle). In addition, after the first reference performance test RPT_1 is completed, a second reference performance test RPT_2 may be conducted after progression of N charge and discharge cycles (e.g., an N+1th charge and discharge cycle to a 2N^{th} charge and discharge cycle). The charge and discharge cycle may proceed under a first charge and discharge rate C1 similar to the actual usage environment of the secondary battery, and the reference performance test RPT may be conducted under a second charge and discharge rate C2 lower than the first charge and discharge rate C1.

In an embodiment, the lifetime evaluation device may receive battery capacity data of the secondary battery over multiple charge and discharge cycles. Particularly, the lifetime evaluation device may receive initial battery capacity data Q₀ of the secondary battery. In some embodiments, the initial battery capacity data Q₀ may be obtained through an initial reference performance test RPT_0 prior to the start of the charge and discharge cycle of the secondary battery, but other embodiments may not be limited thereto.

The lifetime evaluation device may receive battery capacity data produced for charge and discharge cycles before and after the reference performance test. For example, the lifetime evaluation device may receive first battery capacity data Q₁ produced at a charge and discharge cycle (e.g., the N^{th} charge and discharge cycle) immediately before a specific reference performance test among multiple charge and discharge cycles. Additionally, the lifetime evaluation device may receive second battery capacity data Q₂ produced at a charge and discharge cycle (e.g., the N+1th charge and discharge cycle) immediately after the specific reference performance test.

In embodiments corresponding to Table 800, the specific reference performance test is the first reference performance test RPT_1 performed after a progression of multiple charge and discharge cycles, but, in other embodiments, the specific reference performance test may be any of multiple reference performance tests.

A component of the lifetime evaluation device (e.g., the parameter determiner 134 of the lifetime evaluation device 130 in FIG. 1) may determine a second degradation prediction parameter Q_{P} based on the received initial battery capacity data Q₀, first battery capacity data Q₁, and second battery capacity data Q₂. Particularly, the second degradation prediction parameter Q_{P} may be determined as a ratio (%) of the difference value between the first battery capacity data Q₁ and the second battery capacity data Q₂ with respect to the initial battery capacity data Q₀

$$( e . g . , {Q}_{P} = \frac{\vert Q 1 - Q 2 \vert}{Q 0} ) .$$

In some embodiments, initial battery capacity data Q₀ may be determined based on the discharge capacity of the secondary battery, and the first battery capacity data Q₁ and the second battery capacity data Q₂ may be determined based on the charge capacity of the secondary battery, but other embodiments are not limited thereto.

In an embodiment, a component of the lifetime evaluation device (e.g., lifetime evaluator 136 of the lifetime evaluation device 130 in FIG. 1) may determine whether the positive electrode of the secondary battery is deteriorated based on the second degradation prediction parameter. For example, the lifetime evaluation device may compare the second degradation prediction parameter Q_{P} with the preset threshold ratio Q_{C}. If the second degradation prediction parameter Q_{P} is greater than the preset threshold ratio Q_{C}, the lifetime evaluation device may determine that the positive electrode of the secondary battery is deteriorated. In addition, if the second degradation prediction parameter Q_{P} is less than the preset threshold ratio Q_{C}, the lifetime evaluation device may determine that the positive electrode of the secondary battery is not deteriorated. In some embodiments, the threshold ratio Q_{C} may be 1 percent or less, but other embodiments are not limited to the aforementioned range.

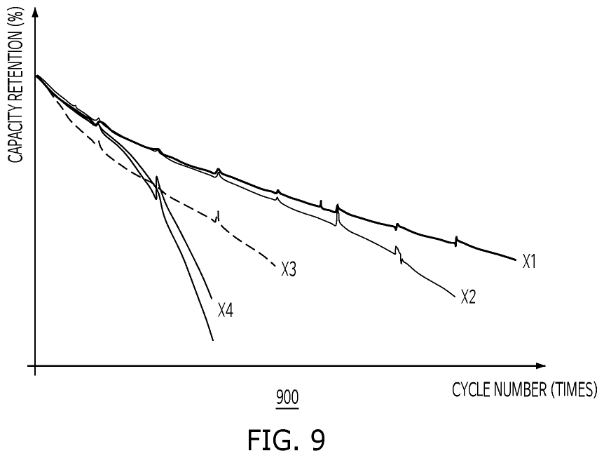

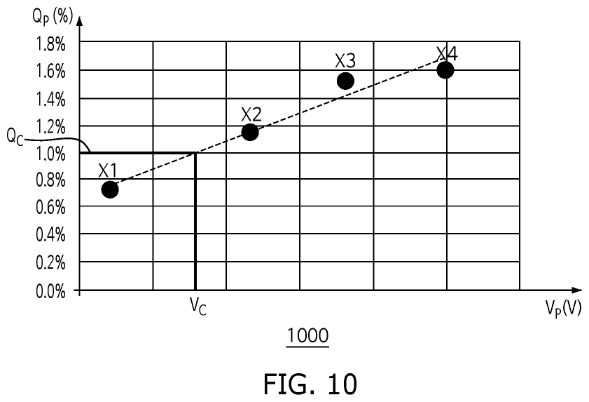

In an embodiment, a first degradation prediction parameter V_{P} determined based on voltage data of the secondary battery may be associated with a second degradation prediction parameter Q_{P} determined based on battery capacity data of the secondary battery. Hence, a threshold voltage V_{C} for the first degradation prediction parameter V_{P} may be determined based on a threshold ratio Q_{C} for the second degradation prediction parameter Q_{P}. The correlation between the first degradation prediction parameter V_{P} and the second degradation prediction parameter Q_{P} will be described with reference to FIGS. 9 and 10.

FIG. 9 is a graph showing a correlation between the first degradation prediction parameter and the second degradation prediction parameter. The graph 900 represents experiment data and shows a calculated trend of capacity retention ratios (%) of secondary batteries over multiple charge and discharge cycles in graphed examples including a first example X1, a second example X2, a third example X3, and a fourth example X4. In the graphed examples, all the secondary batteries were tested on cells in a shipping-charged state after completion of formation, and a total of 1,000 charge and discharge cycles were performed, and a reference performance test RPT was performed every 100 charge and discharge cycles. Particularly, for the charge and discharge cycle, each of the secondary batteries in the graphed examples was charged at 0.5 C in the CC charging section S1, charged at 4.25 V in the CV charging section S2, rested for 10 minutes in the rest after charging section S3, discharged at 0.5 C and 2.5 V in the CC discharging section S4, and rested for 10 minutes in the rest after discharging section S5. Additionally, for the reference performance test RPT, each secondary battery was charged at 0.33 C in the CC charging section S1, charged at 4.25 V in the CV charging section S2, rested for 10 minutes in the rest after charging section S3, discharged at 0.33 C and 2.5 V in the CC discharging section S4, and rested for 10 minutes in the rest after discharging section S5.

Referring to the graph 900, it may be identified that the change in the capacity retention ratio (%) of the secondary battery over multiple charge and discharge cycles is the smallest in the first example X1. Additionally, it may be identified that the change in the capacity retention ratio (%) of the secondary battery over multiple charge and discharge cycles is largest in the fourth example (X4). That is, it may be seen that degradation of the positive electrode has progressed the least in the secondary battery of the first example X1, and degradation of the positive electrode has progressed the most in the secondary battery of the fourth example X4.

FIG. 10 is another graph showing a correlation between a first degradation prediction parameter and a second degradation prediction parameter. More particularly, FIG. 10 is a graph 1000 showing a correlation between the first degradation prediction parameter V_{P} and the second degradation prediction parameter Q_{P} for the secondary batteries in the graphed examples.

Referring to the figures on the y-axis of the graph 1000, the second degradation prediction parameter Q_{P} may be identified for each of the secondary batteries in the graphed examples. In the case of the first example X1, the second degradation prediction parameter Q_{P} was calculated to be about 0.7%, which was less than the threshold ratio Q_{C}. Additionally, for the second example X2, the third example X3, and the fourth example X4, the second degradation prediction parameters Q_{P} were calculated to be about 1.1%, 1.5%, and 1.6%, respectively, indicating that each second degradation prediction parameter Q_{P} was greater than the threshold ratio Q_{C}. Consequently, the lifetime evaluation device may determine that there is a risk of degradation in the secondary batteries of the graphed examples.

Referring to the graph 1000, it may be confirmed that there is a positive correlation between the first degradation prediction parameter V_{P} and the second degradation prediction parameter Q_{P}. Particularly, in the first example X1 where the second degradation prediction parameter Q_{P} was determined to be a smallest value when compared to the other examples of the graphed examples, the first degradation prediction parameter V_{P} was also determined to be a smallest value when compared to the other examples of the graphed examples. Similarly, in the fourth example X4 where the second degradation prediction parameter Q_{P} was determined to be the largest value when compared to the other examples of the graphed examples, the first degradation prediction parameter V_{P} was also determined to be the largest value when compared to the other examples of the graphed examples. That is, it may be seen that the first degradation prediction parameter V_{P} increases approximately proportionally as the second degradation prediction parameter Q_{P} increases.

In an embodiment, the threshold voltage V_{C} for the first degradation prediction parameter V_{P} may be determined based on the threshold ratio Q_{C} for the second degradation prediction parameter Q_{P}. For example, the threshold voltage V_{C} for the first degradation prediction parameter V_{P} may be calculated by using a linear regression model technique. As a further example, referring to the graph 1000, the voltage value corresponding to the threshold ratio Q_{C} for the second degradation prediction parameter Q_{P} may be the threshold voltage V_{C} for the first degradation prediction parameter V_{P}.

Thus, the lifetime characteristics of a secondary battery may be evaluated on the basis of both the first degradation prediction parameter V_{P} and the second degradation prediction parameter Q_{P}, both of which are calculated based on the monitoring data of the secondary battery. Hence, the accuracy of the lifetime evaluation results can be increased by cross validating the life evaluation results.

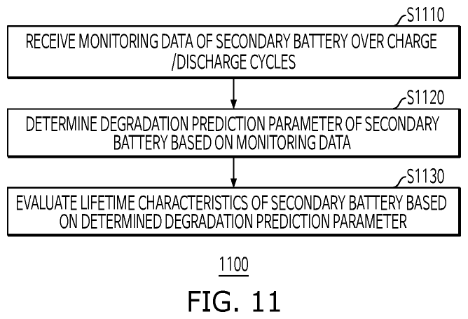

FIG. 11 is a flowchart for a method of evaluating the lifetime of a secondary battery according to some embodiments of the present disclosure. The lifetime evaluation method 1100 for a secondary battery may be initiated by receiving monitoring data of the secondary battery over charge and discharge cycles S1110. The monitoring data may include at least one of voltage data, current data, or battery capacity data of the secondary battery over multiple charge and discharge cycles.

Each of the multiple charge and discharge cycles may include, in sequence, a CC charging section in which the secondary battery is charged at a constant current, a CV charging section in which the secondary battery is charged at a constant voltage, a rest after charging section in which charging of the secondary battery is stopped, a CC discharging section in which the secondary battery is discharged at a constant current, and a rest after discharging section in which discharging of the secondary battery is stopped.

In an embodiment, a reference performance test may be conducted every preset number of charge and discharge cycles among multiple charge and discharge cycles. The preset number of charge and discharge cycles may be greater than or equal to 1 and less than or equal to 200. In addition, multiple charge and discharge cycles may proceed under a preset first charge and discharge rate condition, and the reference performance test may be conducted under a second charge and discharge rate that is lower than the first charge and discharge rate. In some embodiments, the second charge and discharge rate may be 10 to 50 percent of the first charge and discharge rate, but other embodiments are not limited to the aforementioned range.

Thereafter, based on the monitoring data, the degradation prediction parameter of the secondary battery may be determined S1120. Then, based on the determined degradation prediction parameter, lifetime characteristics of the secondary battery may be evaluated S1130.

In one embodiment, a step of determining the degradation prediction parameter may include a step of determining the voltage data of the secondary battery—measured at an end time of the rest after discharging section of a specific charge and discharge cycle—as a degradation prediction parameter of the secondary battery. The specific charge and discharge cycle may be the first charge and discharge cycle among multiple charge and discharge cycles. In addition, if the degradation prediction parameter is greater than a preset threshold voltage, the positive electrode of the secondary battery may be determined to be deteriorated.

In another embodiment, the step of receiving monitoring data may include a step of receiving initial battery capacity data of the secondary battery, first battery capacity data obtained at a charge and discharge cycle immediately before a specific reference performance test, and second battery capacity data obtained at a charge and discharge cycle immediately after the specific reference performance test. In addition, the step of determining the degradation prediction parameter may include a step of determining the degradation prediction parameter based on the initial battery capacity data, the first battery capacity data, and the second battery capacity data. For example, the degradation prediction parameter may be determined to be a ratio of the difference between the first battery capacity data and the second battery capacity data with respect to the initial battery capacity data. The threshold ratio may be less than or equal to 1 percent. Further, a step of evaluating the lifetime characteristics of the secondary battery may include a step of determining whether the positive electrode of the secondary battery is deteriorated, whereof the positive electrode of the secondary battery is deteriorated if the determined degradation prediction parameter is greater than the preset threshold ratio.

The flowchart of FIG. 11 and related descriptions thereof are only exemplary of some embodiments of present disclosure, and the scope of the present disclosure is not limited to the flowchart of FIG. 11 and the description above. For example, in the flowchart and the related description above, one or more steps may be added, changed, and/or deleted; the order of one or more steps may be changed; and/or one or more steps may be executed simultaneously.

Although the present disclosure has been described above with respect to embodiments thereof, the present disclosure is not limited thereto. Various modifications and variations can be made thereto by those skilled in the art within the spirit of the present disclosure.

### DESCRIPTION OF SOME REFERENCE SYMBOLS

100: lifetime evaluation system
110: battery
120: charging device
130: lifetime evaluation device
132: data receiver
134: parameter determiner
136: lifetime evaluator

What is claimed is:

1. A method of evaluating a lifetime of a secondary battery, the method comprising:
receiving, via a data receiver, monitoring data of the secondary battery over charge and discharge cycles;
determining, via a parameter determiner, a degradation pre diction parameter of the secondary battery based on the monitoring data; and
evaluating, via a lifetime evaluator, lifetime characteristics of the secondary battery based on the degradation prediction parameter.

2. The method as claimed in claim 1, further comprising receiving monitoring data including at least one of voltage data, current data, or battery capacity data of the secondary battery over multiple charge and discharge cycles.

3. The method as claimed in claim 2, wherein each of the multiple charge and discharge cycles includes, in sequence, a constant current charging section in which the secondary battery is charged at a constant current, a constant voltage charging section in which the secondary battery is charged at a constant voltage, a rest after charging section in which charging of the secondary battery is stopped, a constant current discharging section in which the secondary battery is discharged at a constant current, and a rest after discharging section in which discharging of the secondary battery is stopped, the method further comprising computing voltage data of the secondary battery measured at an end time of the rest after discharging section of a specific charge and discharge cycle to determine the degradation prediction parameter of the secondary battery.

4. The method as claimed in claim 3, wherein computing voltage data of the secondary battery measured at an end time of the rest after discharging section of the specific charge and discharge cycle further comprises computing voltage data of the secondary battery measured at an end time of the rest after discharging section of a first charge and discharge cycle, the first charge and discharge cycle being the specific charge and discharge cycle.

5. The method as claimed in claim 3, wherein evaluating lifetime characteristics of the secondary battery further comprises determining whether a positive electrode of the secondary battery is deteriorated, the positive electrode of the secondary battery being deteriorated when the degradation prediction parameter is greater than or equal to a preset threshold voltage.

6. The method as claimed in claim 2, further comprising conducting a reference performance test of the secondary battery once for every preset number of charge and discharge cycles among the multiple charge and discharge cycles.

7. The method as claimed in claim 6, wherein receiving monitoring data further comprises receiving (i) initial battery capacity data of the secondary battery, (ii) first battery capacity data obtained at a charge and discharge cycle immediately before a specific reference performance test, and (iii) second battery capacity data obtained at a charge and discharge cycle immediately after the specific reference performance test, and
wherein determining a degradation prediction parameter further comprises determining the degradation prediction parameter based on (i) the initial battery capacity data, (ii) the first battery capacity data, and (iii) the second battery capacity data.

8. The method as claimed in claim 7, wherein determining the degradation prediction parameter further comprises determining a ratio of a difference between the first battery capacity data and the second battery capacity data.

9. The method as claimed in claim 8, wherein evaluating lifetime characteristics of the secondary battery further comprises determining whether a positive electrode of the secondary battery is deteriorated, the positive electrode of the secondary battery being deteriorated when the determined degradation prediction parameter is greater than or equal to a preset threshold ratio.

10. The method as claimed in claim 9, further comprising setting the preset threshold ratio to less than or equal to 1 percent.

11. The method as claimed in claim 6, further comprising:
performing the multiple charge and discharge cycles having a preset first charge and discharge rate;
and conducting the reference performance test under a second charge and discharge rate that is lower than the preset first charge and discharge rate.

12. The method as claimed in claim 11, wherein conducting the reference performance test under a second charge and discharge rate further comprises conducting the reference performance test under a second charge and discharge rate that is 10 to 50 percent of the preset first charge and discharge rate.

13. The method as claimed in claim 6, further comprising performing the multiple charge and discharge cycles at a preset number of charge and discharge cycles that is greater than or equal to 1 and less than or equal to 200.

14. A device for evaluating a lifetime of a secondary battery, the device comprising:
a data receiver configured to receive monitoring data of the secondary battery over charge and discharge cycles;
a parameter determiner configured to determine a degradation prediction parameter of the secondary battery based on the monitoring data; and
a lifetime evaluator configured to evaluate lifetime characteristics of the secondary battery based on the degradation prediction parameter.

15. The device as claimed in claim 14, wherein the monitoring data includes at least one of voltage data, current data, or battery capacity data of the secondary battery over multiple charge and discharge cycles.

16. The device as claimed in claim 15, wherein each of the multiple charge and discharge cycles includes, in sequence, a constant current charging section in which the secondary battery is charged at a constant current, a constant voltage charging section in which the secondary battery is charged at a constant voltage, a rest after charging section in which charging of the secondary battery is stopped, a constant current discharging section in which the secondary battery is discharged at a constant current, and a rest after discharging section in which discharging of the secondary battery is stopped,
wherein the parameter determiner is configured to determine the degradation prediction parameter of the secondary battery by computing voltage data of the secondary battery, the voltage data measured at an end time of the rest after discharging section of a specific charge and discharge cycle, and
wherein the lifetime evaluator is configured to determine that a positive electrode of the secondary battery is deteriorated when the degradation prediction parameter is greater than or equal to a preset threshold voltage.

17. The device as claimed in claim 16, wherein the specific charge and discharge cycle is a first charge and discharge cycle among the multiple charge and discharge cycles.

18. The device as claimed in claim 15, wherein a reference performance test of the secondary battery is conducted once for every preset number of charge and discharge cycles among the multiple charge and discharge cycles,
wherein the data receiver is configured to receive (i) initial battery capacity data of the secondary battery, (ii) first battery capacity data obtained at a charge and discharge cycle immediately before a specific reference performance test, and (iii) second battery capacity data obtained at a charge and discharge cycle immediately after the specific reference performance test,
wherein the parameter determiner is configured to determine the degradation prediction parameter based on (i) the initial battery capacity data, (ii) the first battery capacity data, and (iii) the second battery capacity data, and
wherein the lifetime evaluator is configured to determine whether a positive electrode of the secondary battery is deteriorated, the positive electrode being deteriorated when the determined degradation prediction parameter is greater than or equal to a preset threshold ratio.

19. The device as claimed in claim 18, wherein the degradation prediction parameter is determined to be a ratio of a difference between the first battery capacity data and the second battery capacity data with respect to the initial battery capacity data.

20. The device as claimed in claim 19, wherein the preset threshold ratio is less than or equal to 1 percent.
